(19) United States
(12) Patent Application Publication
(10) Pub. No.: US 2018/0087179 A1
(43) Pub. Date: Mar. 29, 2018

(54) SINGLE CRYSTAL SILICON INGOTS HAVING DOPED AXIAL REGIONS WITH DIFFERENT RESISTIVITY AND METHODS FOR PRODUCING SUCH INGOTS

(71) Applicant: Corner Star Limited, Kowloon (HK)

(72) Inventors: Salvador Zepeda, St. Peters, MO (US); Soubir Basak, Chandler, AZ (US)

(21) Appl. No.: 15/712,495

(22) Filed: Sep. 22, 2017

Related U.S. Application Data
(60) Provisional application No. 62/401,030, filed on Sep. 28, 2016.

(51) Int. Cl. C30B 15/04; C30B 15/00; C30B 29/06

(52) U.S. Cl. CPC C30B 15/04; C30B 29/06; C30B 15/002

(57) ABSTRACT

Methods for producing single crystal ingots having doped axial resistivity regions with different resistivities and methods for producing such ingots are disclosed. In some embodiments, first and second target resistivities are determined for first and second doped axial regions. The melt is contacted with a seed crystal and pulled away from the melt to grow a single crystal ingot having the first and second doped axial regions. The addition of dopant to the melt is controlled such that the first doped axial region has the first target resistivity and the second doped axial region has the second target resistivity.

### CROSS-REFERENCE TO RELATED APPLICATION

This application claims the benefit of U.S. Provisional Patent Application No. 62/401,030, filed Sep. 28, 2016, which is incorporated herein by reference in its entirety.

### FIELD OF THE DISCLOSURE

The field of the disclosure relates generally to methods for producing single crystal ingots having doped axial regions with different average resistivities and methods for producing such ingots by a continuous Czochralski process. More particularly, the methods involve controlling addition of dopant to a silicon melt such that each of the first and second doped axial regions has a target resistivity. In some embodiments, dopant concentration in the melt is controlled by a model.

### BACKGROUND

In the production of silicon crystals grown by the continuous Czochralski (cCZ) method, polycrystalline silicon is first melted within a crucible, such as a quartz crucible, of a crystal pulling device to form a silicon melt. The puller then lowers a seed crystal into the melt and slowly raises the seed crystal out of the melt. As the seed crystal is grown from the melt, solid polysilicon or liquid silicon is continuously added to the melt to replenish the silicon that is incorporated into the growing crystal.

Suitable amounts of dopants are continuously added to the melt to modify the base resistivity of the resulting monocrystalline ingot. Due to increased specificity in the solar and semiconductor fields, customer orders often require less wafers than the number produced from a single ingot. This results in increased inventory of unused wafers within a particular resistivity range.

A need exists for methods for producing single crystal silicon ingots in a continuous Czochralski process that allow at least two discreet axial doped regions having different resistivities to be produced with the resistivity in each region, with axial uniformity within each region.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method of growing a single crystal silicon ingot from a melt. The melt includes an inner melt zone separated from an outer melt zone by one or more fluid barriers. The single crystal silicon ingot has a constant diameter portion with a first doped axial region and a second doped axial region. A first target resistivity for the first doped axial region is determined. A second target resistivity for the second doped axial region is determined. The second target resistivity is different than the first target resistivity. The melt is contacted with a seed crystal within the inner melt zone to initiate crystal growth. The seed crystal is pulled away from the melt to grow a single crystal ingot having the first doped axial region and the second doped axial region. The addition of dopant to the melt is controlled such that the first doped axial region has the first target resistivity. The addition of dopant to the melt is controlled such that the second doped axial region has the second target resistivity.

Another aspect of the present disclosure is directed to a method of growing a single crystal silicon ingot having a first doped axial region and a second doped axial region from a melt. The melt includes an inner melt zone separated from an outer melt zone by one or more fluid barriers. The melt is contacted with a seed crystal within the inner melt zone to initiate crystal growth. The seed crystal is pulled away from the melt to grow a single crystal ingot. The ingot has a neck region, a shoulder region, and a constant diameter portion. A dopant concentration of the inner melt zone is controlled such that the constant diameter portion has a first doped axial region and a second doped axial region. The first doped axial region has an average resistivity that is different than an average resistivity of the second doped axial region. Control of the dopant concentration of the inner melt zone includes using a model to predict the dopant concentration of the melt in the inner melt zone.

Yet a further aspect of the present disclosure is directed to a single crystal silicon ingot. The ingot has a constant diameter region. The constant diameter portion has a first doped axial region and a second doped axial region. Each of the first and second doped regions are doped with an electrically active dopant. The first doped axial region has an average resistivity that is at least about 0.1 mΩ-cm less than an average resistivity of the second doped axial region. The first doped axial region and the second doped axial region both have a length of at least about 750 mm. The resistivity within the first axial region varies by no more than 15% and the resistivity within the second axial region varies by no more than 15%.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section of an system for growing single crystal silicon ingots by a continuous Czochralski method;

FIG. 2 is a schematic representation of a crystal growing system illustrating different transport mechanisms of a dopant during a continuous Czochralski growth process;

FIG. 3 is a flow chart of an method of growing a single crystal ingot from a melt of semiconductor or solar material;

FIG. 4 is a flow chart of another method of growing a single crystal ingot from a melt of semiconductor or solar material;

FIG. 5 is an ingot having two doped axial regions grown by a continuous Czochralski method; and

FIG. 6 is a plot of measured and modeled resistivity values from a doped monocrystalline ingot grown by a continuous Czochralski method.

Corresponding reference characters indicate corresponding parts throughout the drawings.

### DETAILED DESCRIPTION

The Czochralski growth methods described herein enable the production of multiple, single crystal silicon semiconductor and solar grade ingots that each includes two or more discreet doped axial regions having different average resistivities. In particular, the present disclosure provides methods for controlling the axial resistivity profile of ingots grown by the continuous Czochralski (cCz) method using a model to predict dopant concentration of the growth zone of a melt at any point during the cCZ process. Referring to

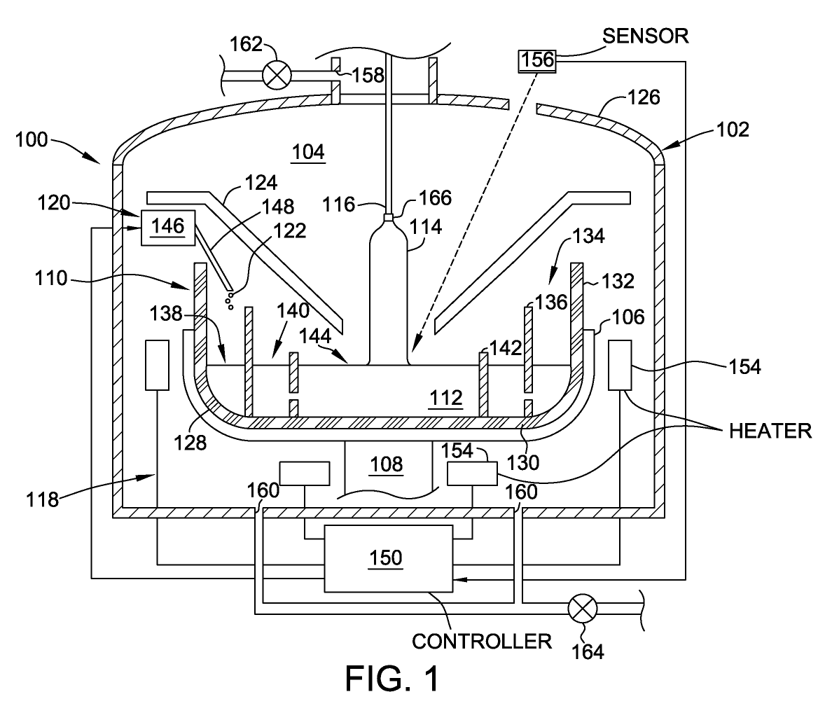

FIG. 1, one suitable apparatus for carrying out the methods described herein is shown schematically in the form of a crystal growing system, and is indicated generally at 100.

The illustrated crystal growing system 100 includes a housing 102 defining a growth chamber 104, a susceptor 106 supported by a rotatable shaft 108, a crucible assembly 110 that contains a melt 112 of semiconductor or solar grade material (e.g., silicon) from which an ingot 114 is being pulled by a crystal puller 116, and a heating system 118 for supplying thermal energy to the system 100. The illustrated system 100 also includes a feed system 120 for feeding solid or liquid feedstock material 122 and dopants into the crucible assembly 110 and/or the melt 112, and a heat shield 124 configured to shield the ingot 114 from radiant heat from the melt 112 to allow the ingot 114 to solidify.

The housing 102 encloses the susceptor 106, the crucible assembly 110, and portions of the heating system 118 within the growth chamber 104. The housing 102 includes an upper dome 126, which may include one or more view ports to enable an operator to monitor the growth process. In use, the housing 102 may be used to seal the growth chamber 104 from the external environment. Suitable materials from which the housing 102 may be constructed include, but are not limited to, stainless steel.

The crucible assembly 110 includes a crucible 128 having a base 130 and a generally annular sidewall 132 extending around the circumference of the base 130. Together, the base 130 and the sidewall 132 define a cavity 134 of the crucible 128 within which the melt 112 is disposed. The crucible 128 may be constructed of any suitable material that enables the system 100 to function as described herein including, for example, quartz.

The crucible assembly 110 also includes a plurality of weirs or fluid barriers that separate the melt 112 into different melt zones. In the illustrated embodiment, the crucible assembly 110 includes a first weir 136 (broadly, a fluid barrier) separating an outer melt zone 138 of the melt 112 from an inner melt zone 140 of the melt 112, and a second weir 142 (broadly, a fluid barrier) at least partially defining a growth zone 144 from which the crystal ingot 114 is pulled. The first weir 136 and the second weir 142 each have a generally annular shape, and have at least one opening defined therein to permit the melt 112 to flow radially inward towards the growth zone 144. The first weir 136 and the second weir 142 are disposed within the cavity 134 of the crucible 128, and create a circuitous path from the outer melt zone 138 to the inner melt zone 140 and the growth zone 144. The weirs 136, 142 thereby facilitate melting solid feedstock material 122 before it reaches an area immediately adjacent to the growing crystal (e.g., the growth zone 144). The weirs 136, 142 may be constructed from any suitable material that enables the system 100 to function as described herein, including, for example, quartz. While the illustrated embodiment is shown and described as including two weirs, the system 100 may include any suitable number of weirs that enables the system 100 to function as described herein, such as one weir, three weirs, or four or more weirs.

The crucible 128, the first weir 136, and the second weir 142 may be formed separately from one another, and assembled to form the crucible assembly 110. In other suitable embodiments, the crucible assembly 110 may have a unitary construction. That is, the crucible 128 and one or both weirs 136, 142 may be integrally formed (e.g., formed from a unitary piece of quartz).

The feed system 120 includes a feeder 146 and a feed tube 148. Feedstock material 122 and/or dopant material may be placed into the outer melt zone 138 from the feeder 146 through the feed tube 148 to replenish the melt 112 and maintain a desired dopant concentration in the melt 112. The amount of feedstock material 122 and dopant added to the melt 112 may be controlled by a controller (such as the controller 150, described below). In the illustrated embodiment, a single feed system 120 is used to feed both feedstock material 122 and dopant material into the melt 112. In other embodiments, separate feed systems may be employed to feed feedstock material 122 and dopant material into the melt 112. The feedstock material 122 supplied to the outer melt zone 138 may be solid or liquid. In some embodiments, the feedstock material 122 is polycrystalline silicon.

The heat shield 124 is positioned adjacent the crucible assembly 110, and separates the melt 112 from an upper portion of the system 100. The heat shield 124 is configured to shield the ingot 114 from radiant heat generated by the melt 112 and the heating system 118 to allow the ingot 114 to solidify. In the example embodiment, the heat shield 124 includes a conical member separating the melt 112 from an upper portion of the system 100, and a central opening defined therein to allow the ingot 114 to be pulled therethrough. In other embodiments, the heat shield 124 may have any suitable configuration that enables the system 100 to function as described herein. In the example embodiment, the heat shield 124 is constructed from graphite. In other embodiments, the heat shield 124 may be constructed from any suitable material that enables the system 100 to function as described herein, including, for example, silica-coated graphite, high purity molybdenum, and combinations thereof.

The heating system 118 is configured to melt an initial charge of solid feedstock material (such as chunk polysilicon), and maintain the melt 112 in a liquified state after the initial charge is melted. The heating system 118 includes a plurality of heaters 154 arranged at suitable positions about the crucible assembly 110. In the illustrated embodiment, each heater 154 has a generally annular shape. The illustrated heating system 118 includes two heaters 154. One heater is positioned beneath the crucible 128 and the susceptor 106, and one heater is positioned around and radially outward of the sidewall 132 of the crucible 128.

In the example embodiment, the heaters 154 are resistive heaters, although the heaters 154 may be any suitable heating device that enables the system 100 to function as described herein. Further, while the illustrated embodiment is shown and described as including two heaters 154, the system 100 may include any suitable number of heaters 154 that enables the system 100 to function as described herein.

The heaters 154 are connected to the controller 150, which controls the electric energy provided to the heaters 154 to control the amount of thermal energy supplied by the heaters 154. The amount of current supplied to each of the heaters 154 by the controller 150 may be separately and independently controlled to optimize the thermal characteristics of the melt 112. In the illustrated embodiment, the controller 150 also controls feed system 120 and the delivery of feedstock material 122 to the melt 112 to control the temperature of the melt 112.

A sensor 156, such as a pyrometer or similar temperature sensor, provides a continuous measurement of the temperature of the melt 112 at the crystal/melt interface of the growing single crystal ingot 114. Sensor 156 also may be configured to measure the temperature of the growing ingot 114. Sensor 156 is communicatively coupled with controller 150. While a single communication lead is shown for clarity, one or more temperature sensor(s) may be linked to the controller 150 by multiple leads or a wireless connection, such as by an infra-red data link or another suitable means.

During a Czochralski growth process, a carrier gas may be introduced into the growth chamber 104 through one or more gas inlets 158 to remove evaporated species and particulates from the growth chamber 104. Gas introduced through the gas inlets 158 is exhausted through one or more exhaust outlets 160.

The gas inlets 158 are connected in fluid communication with a suitable inert gas source (not shown). Suitable inert gasses include, for example and without limitation, argon, helium, nitrogen, neon, and combinations thereof. Gas introduced through the gas inlets 158 flows generally downward within the growth chamber 104, and across the surface of the melt 112. The flow rate of gas through the gas inlet 158 (i.e., the inlet flow rate) may be controlled using one or more flow controllers 162. The flow controllers 162 may include any suitable device or combination of devices that enables the crystal growing system 100 to function as described herein including, for example and without limitation, mass flow controllers, volumetric flow controllers, throttle valves, and butterfly valves.

Gas introduced through gas inlets 158 is exhausted through exhaust outlets 160. The exhaust outlets 160 may be connected to an exhaust fan or pump (not shown) to remove inert gases from the growth chamber, along with evaporated species and particulates carried by the inert gas. The exhaust outlets 160 are also connected in fluid communication with a pressure controller 164 configured to control an operating pressure within the growth chamber 104 during a growth process. The pressure controller 164 may include any suitable device or combination of devices that enable the crystal growing system to function as described herein including, for example and without limitation, electronic pressure controllers, throttle valves, butterfly valves, ball valves, pumps, and fans. The pressure controller 164 may be operated independent of or in conjunction with an exhaust fan or pump connected to the exhaust outlets.

The localized flow rate of gas across the surface of the melt 112 may vary from the inlet flow rate due to varying sizes of gas flow passages defined between the melt surface and components of the crystal growing system 100, such as the heat shield 124. As described in more detail herein, the localized gas flow rate across the surface of the melt 112 may be controlled by adjusting the operating pressure within the growth chamber 104 and/or the inlet flow rate of the carrier gas.

During the continuous Czochralski growing process, an initial charge of semiconductor or solar material, such as polycrystalline silicon, is melted in the crucible 128. A desired type and amount of dopant is added to the melt 112 to modify the base resistivity of the resulting ingot 114. A seed crystal 166 connected to the crystal puller 116 is lowered into contact with the melt 112, and then slowly raised from the melt 112. As the seed crystal 166 is slowly raised from the melt 112, atoms from the melt 112 align themselves with and attach to the seed crystal 166 to form the ingot 114. Feedstock material 122 and additional dopant is added to melt 112 while the ingot 114 is pulled from the melt 112 to replenish the melt 112 and maintain the desired dopant concentration in the melt 112.

The resistivity of the ingot 114 is inversely related to dopant concentration of the ingot 114, which is directly related to the dopant concentration of the inner melt zone from which the ingot is grown. Maintaining the dopant concentration of the inner melt zone near a target concentration during the ingot growing process is desirable to obtain an ingot with a substantially uniform axial resistivity in two or more axial regions having different resistivities. For certain applications, it is desirable that the ingot have a relatively low resistivity, such as no more than about 30 milliohm-centimeters (mΩ-cm), no more than about 20 mΩ-cm, no more than about 10 mΩ-cm, no more than about 3 mΩ-cm, or even no more than about 2 mΩ-cm. Obtaining ingots with such low resistivities requires the melt from which the ingots are grown to have a high dopant concentration.

The dopant added to the melt may include any suitable electrically active dopant material used for semiconductor and solar materials including, for example and without limitation, boron, phosphorous (including red phosphorous), indium, antimony, aluminum, arsenic, gallium, and combinations thereof. The methods and models described herein are also suitable for use with group IV dopants, such as germanium. In some embodiments, the dopant includes an N-type dopant selected from the group consisting of phosphorus, arsenic, and antimony, or a P-type dopant selected from the group consisting of boron, aluminum, gallium and indium. In other embodiments, the dopant added to the melt may include more than one type of dopant. For example, the dopant may include an N-type dopant and a P-type dopant.

The methods and models described herein are particularly well suited for use with relatively volatile dopants. In some embodiments, for example, the dopant added to the melt in this method is selected from the group consisting of indium, antimony, arsenic, and red phosphorous.

In one aspect, the present disclosure provides a method of controlling the dopant concentration within the inner melt zone using a model to predict the dopant concentration within the inner melt zone during the Czochralski growth process. In this manner, the dopant concentration may be controlled to prepare two doped axial regions have different resistivities in the ingot. In particular, a model is provided to account for the numerous dopant transport mechanisms that affect the dopant concentration within different melt zones of a melt over the course of a Czochralski growth process. The transport mechanisms affecting dopant concentration within the melt include dopant evaporation, convective mass transport between adjacent melt zones, diffusion between adjacent melt zones resulting from dopant concentration gradients, and dopant segregation from the ingot being grown. Also affecting dopant concentration is additional dopant and melt material added to the melt throughout the Czochralski growth process.

By accounting for each of the above-described transport mechanisms, the evolution of dopant concentration within each melt zone over time can be expressed using the following generalized differential equation:

$$\frac{{dN}_{i} ( t )}{dt} = - {k}_{eff} ( \dot{v} , CR , XR ) \dot{v} ( t ) \frac{{N}_{i} ( t )}{{V}_{i}} + fr ( t ) + {D}_{i , i + 1} ( t ) {A}_{i , i + 1} \frac{\frac{{N}_{i + 1} ( t )}{{V}_{i + 1}} - \frac{{N}_{i} ( t )}{{V}_{i}}}{{I}_{i , i + 1}} - {D}_{i - 1 , i} ( t ) {A}_{i - 1 , i} \frac{\frac{{N}_{i} ( t )}{{V}_{i}} - \frac{{N}_{i - 1} ( t )}{{V}_{i - 1}}}{{I}_{i - 1 , i}} - \dot{v} ( t ) \frac{{N}_{i} ( t )}{{V}_{i}} + \dot{v} ( t ) \frac{{N}_{i + 1} ( t )}{{V}_{i + 1}} - g ( P , L , HR , CR , XR , t ) SA ( t ) \frac{{N}_{i} ( t )}{{V}_{i}} \qquad Eq . 1$$

where Nᵢ represents the number of dopant atoms in the i^{th} melt zone of a crystal growing system, t represents the elapsed time from a reference point, such as the time at which crystal growth is initiated or the time at which an initial amount of dopant is added to the melt, k_{eff} represents the effective segregation coefficient of the dopant, which is dependent upon the pull speed (\dot{v}) of the crystal ingot, the rotation rate of the crucible (CR), and the rotation rate of the crystal ingot (XR), \dot{v} (t) represents the volumetric flow rate of melt material between melt zones calculated from the ingot pull speed, Vᵢ, represents the volume of the melt in the i^{th} melt zone, fr(t) represents the feed rate of dopant into the i^{th} melt zone, D represents the diffusion coefficient (also referred to as a mass transfer coefficient) between adjacent melt zones, A represents the total cross-sectional area of the openings in the fluid barrier between adjacent melt zones, 1 represents the length of the openings in the fluid barrier between adjacent melt zones, g represents the evaporation coefficient, which is dependent upon the pressure within the crystal pulling system (P), the gas flow rate across the melt surface (L), the spacing between the heat shield and the surface of the melt (HR), the rotation rate of the crucible (CR), the rotation rate of the crystal ingot (XR), and time (t), and SA(t) represents the exposed surface area of the melt zone. In Equation 1, subscripts are used to denote the various melt zones of the crystal growing system, where i+1 indicates the melt zone located adjacent to and radially inward from the i^{th} melt zone, and i−1 represents the melt zone located adjacent to and radially outward from the i^{th} melt zone.

The coefficient terms of Equation 1 (i.e., the segregation coefficient, the diffusion coefficients, and the evaporation coefficient) may also exhibit a dependence upon the setup or geometry of the specific crystal growing system used to grow a crystal ingot. Accordingly, in some embodiments, the segregation coefficient, the diffusion coefficients, and the evaporation coefficient are empirically determined for a specific crystal growing system based on one more Czochralski growth procedures carried out in the crystal growing system. Further, in some embodiments, separate models may be developed for the crystal growing system to approximate one or more of the segregation coefficient, the diffusion coefficients, and the evaporation coefficient as a function of one or more variables, such as crystal ingot pull rate, the pressure within the crystal growing system, the crucible rotation rate, the crystal ingot rotation rate, and the gas flow rate across the melt surface.

As indicated in Equation 1, the dopant concentration of each melt zone is dependent on the dopant concentration of adjoining melt zones. For a given crystal growing system having a determinate number of melt zones, Equation 1 can be used to establish a model that predicts the dopant concentration in each melt zone over the course of a continuous Czochralski method. In particular, applying Equation 1 to each melt zone provides a set of differential equations, one for each melt zone, which represents the dopant concentration in each melt zone as a function of time. The set of differential equations can be used to model and predict the dopant concentration within each melt zone of a crystal growing system over time to provide an accurate estimation of the axial resistivity profile of an ingot grown by the Czochralski method. This information may be used to control dopant addition to the melt to form an ingot having two doped axial regions with different resistivities.

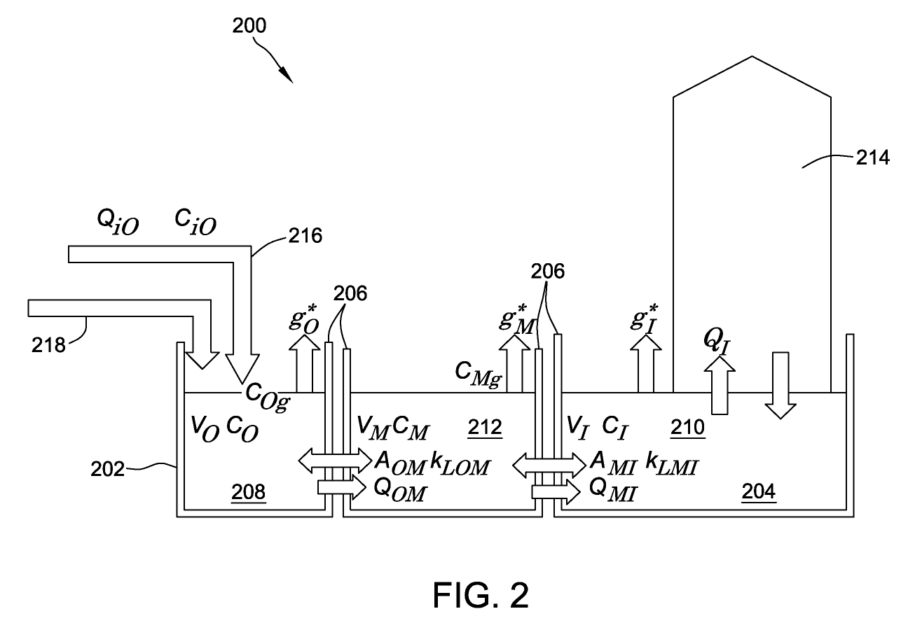

FIG. 2 is a simple schematic representation of a crystal growing system 200 illustrating the different transport mechanisms of a dopant in a three melt zone system. The crystal growing system 200 of FIG. 2 is representative of crystal growing systems having three discrete melt zones, such as the two weir crystal growing system 100 of FIG. 1. The crystal growing system 200 includes a crucible 202 having a melt 204 disposed therein, and weirs or fluid barriers 206 defining an outermost or, more generally, outer melt zone 208, an inner melt zone 210, and a middle or transition melt zone 212 between the outer melt zone 208 and the inner melt zone 210. The transition melt zone 212 may also be considered an outer melt zone relative to the inner melt zone 210. A crystal ingot 214 is grown from the inner melt zone 210 while dopant and feedstock material, indicated by arrows 216 and 218, respectively, are fed to the outer melt zone 208. In some embodiments, dopant may additionally or alternatively be added to the transition melt zone 212. The various transport mechanisms affecting the dopant concentration within the melt 204 are depicted by arrows in FIG. 2 indicating the direction of dopant transport.

Using the crystal growing system illustrated in FIG. 2 as an example, Equation 1 can be expressed as the following set of differential equations:

$$\begin{matrix}\frac{\partial ( {V}_{O} {C}_{O} )}{\partial t} = {Q}_{iO} {C}_{iO} - {Q}_{OM} {C}_{O} - {A}_{O} {g}_{O}^{*} ( {C}_{O} - {C}_{gO} ) - {A}_{OM} {k}_{LOM} ( {C}_{O} - {C}_{M} ) & Eq . 2 \\ \frac{\partial ( {V}_{M} {C}_{M} )}{\partial t} = {Q}_{OM} {C}_{O} - {Q}_{MI} {C}_{M} - {A}_{M} {g}_{M}^{*} ( {C}_{M} - {C}_{gM} ) + {A}_{OM} {k}_{LOM} ( {C}_{O} - {C}_{M} ) - {A}_{MI} {k}_{LMI} ( {C}_{M} - {C}_{I} ) & Eq . 3 \\ \frac{\partial ( {V}_{I} {C}_{I} )}{\partial t} = {Q}_{MI} {C}_{M} - {kQ}_{I} {C}_{I} - {A}_{IC} {g}_{I}^{*} ( {C}_{I} - {C}_{gI} ) + {A}_{MI} {k}_{LMI} ( {C}_{M} - {C}_{I} ) & Eq . 4\end{matrix}$$

where V represents the volume of melt within the respective melt zone, C represents the dopant concentration of the melt within the respective melt zone, t represents the elapsed time from a reference point, such as the time at which crystal growth is initiated or the time at which an initial amount of dopant is added to the melt, Q represents the volumetric flow rate between adjacent melt zones, A represents the surface area of the melt within the respective melt zone, g* represents the evaporation coefficient of the dopant within the respective melt zone, C_{g} represents the dopant concentration in the gas phase adjacent the respective melt zone, k_{L}, represents the mass transfer coefficient between adjacent melt zones, and k represents the effective segregation coefficient of the dopant. In Equations 2-4, subscripts are used to denote the various melt zones of the crystal growing system, where I represents the inner melt zone 210, M represents the middle melt zone 212, and O represents the outer melt zone 208. The term Qᵢₒ represents the volumetric feed rate of melt material into the outer melt zone 208, and the term Cᵢₒ represents the dopant concentration of the melt material being fed into the outer melt zone. Terms from Equations 2-4 are illustrated in FIG. 2 next to the arrow that corresponds to the transport mechanism with which the respective term is associated.

The concentration of dopant within the melt can be determined by solving the three coupled ordinary differential equations represented by Equations 2-4. The terms in Equations 2-4, such as the coefficient terms, may vary over time depending upon the environmental conditions and operating parameters within the crystal growing system. For example, the gas pressure and flow rate during crystal growth may be different from the gas pressure and flow rate during the period between successive crystals being grown, resulting in different evaporation coefficients. Accordingly, in some embodiments, the set of coupled ordinary differential equations are solved for multiple time periods or intervals of the Czochralski growth process.

The concentration of dopant in the crystal ingot can be determined from the dopant concentration in the melt using the equation:

C_{c}=kCₗ Eq. 5

where C_{c} represents the dopant concentration in the crystal ingot, k represents the effective segregation coefficient of the dopant, and Cₗ represents the dopant concentration of the inner melt zone from which the crystal ingot is grown. The resistivity of the crystal ingot can be determined based on the dopant concentration using standard conversion tables and/or formulas known in the art, such as standards SEMI MF723-0307 and SEMI F723-99, published by SEMI International Standards.

Accordingly, the above equations can be used to establish a model to predict the dopant concentration of a melt over the course of a Czochralski growth process. This model can be used to control the dopant concentration within the inner melt zone of a melt and, consequently, to control the axial resistivity profile of an ingot grown from the inner melt zone. The dopant concentration of the inner melt zone can be controlled, for example, by controlling at least one of the initial dopant concentration in one or more melt zones and the dopant feed rate in one or more melt zones based on a target dopant concentration or ingot resistivity.

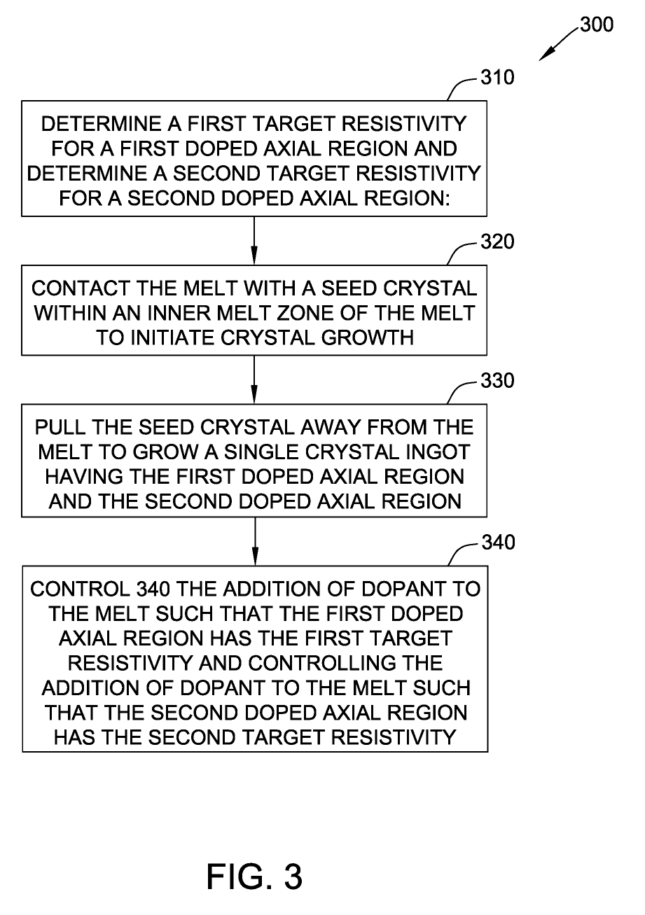

FIG. 3 is a flow chart of an embodiment of a method 300 of growing a single crystal silicon ingot having a first doped axial region and a second doped axial region from a melt including an inner melt zone separated from an outer melt zone by one or more fluid barriers. The method 300 generally includes determining 310 a first target resistivity for a first doped axial region and determining a second target resistivity for a second doped axial region, contacting 320 the melt with a seed crystal within the inner melt zone to initiate crystal growth, pulling 330 the seed crystal away from the melt to grow a single crystal ingot having the first doped axial region and the second doped axial region, and controlling 340 the addition of dopant to the melt such that the first doped axial region has the first target resistivity and controlling the addition of dopant to the melt such that the second doped axial region has the second target resistivity.

Controlling 340 the addition of dopant to the melt to form the first and second doped axial regions generally includes at least one of adding an initial amount of dopant to the outer melt zone to form the first doped axial region and adding a second amount of dopant to the outer melt zone to form the second doped axial region. Alternatively or in addition, controlling 340 the addition of dopant may include adding dopant to the outer melt zone during crystal growth according to a one or more determined dopant feed rates during crystal growth to form the first and second doped axial regions having different resistivities. In some embodiments, the amount(s) of dopant added to the outer melt zone and/or the dopant feed rate are calculated based on the first and second target resistivities using the model to predict the dopant concentration of the melt in the inner melt zone during different stages of ingot growth.

In some embodiments, the target resistivity is a resistivity range or is an upper limit of a resistivity range (e.g., the first target resistivity is a resistivity of less than 2.0 mΩ-cm and the second target resistivity is a resistivity of less than 1.9 mΩ-cm).

The target resistivity of the first and second doped axial regions may also depend upon the dopant added to the melt and the desired resistivities within the ingot. Where the dopant is arsenic, for example, the determined target resistivities of the regions may be no more than about 3 mΩ-cm, more suitably no more than about 2 mΩ-cm, more suitably no more than about 1.6 mΩ-cm, and even more suitably, no more than about 1.5 mΩ-cm. Where the dopant is antimony, the determined target resistivities of the regions may be no more than about 30 mΩ-cm, more suitably no more than about 20 mΩ-cm, and even more suitably, no more than about 10 mΩ-cm. Where the dopant is red phosphorous, the determined target resistivities of the regions may be no more than about 1.7 mΩ-cm, more suitably no more than about 1.2 mΩ-cm, and even more suitably, no more than about 1 mΩ-cm. Where the dopant is boron, the determined target resistivities of the regions may be no more than about 3 mΩ-cm, more suitably no more than about 2 mΩ-cm, and even more suitably, no more than about 1 mΩ-cm. Where the dopant is indium, the determined target resistivities of the regions may be no more than about 5 Ω-cm, more suitably no more than about 3 Ω-cm, and even more suitably, no more than about 2 Ω-cm.

Ingots grown according to the method 300 may be grown along any suitable crystal growth orientation that enables the methods to be performed as described herein. In some embodiments, the method 300 includes growing a crystal ingot along one of a <100>, <110>, and <111> crystal growth orientation using, for example, a seed crystal having the same crystal orientation as the desired crystal growth orientation.

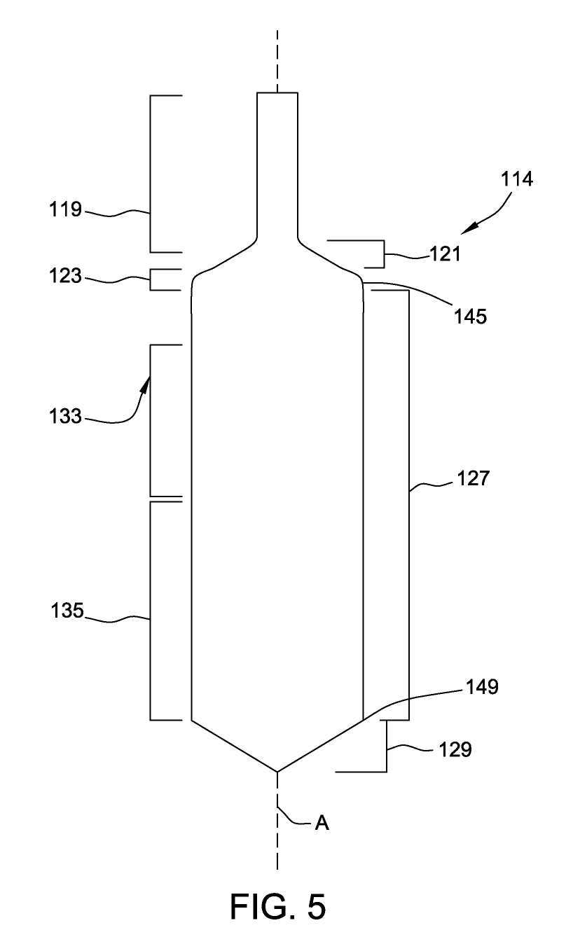

Single crystal silicon ingots 114 grown by embodiments of the present disclosure generally have a neck region 119 (FIG. 5), a taper region 121 in which the ingot widens and a shoulder region 123 in which the ingot transitions from the taper region 121 to a constant diameter portion or “body” 127 of the ingot. The constant diameter portion 127 of the ingot 114 includes the first and second doped axial regions 133, 135 (which may be separated by a transition zone or segment). A central axis A extends through the ingot 114 and through a seed end 145 and a terminal end 149 of the constant diameter region 127. The ingot 114 ends in a crown region (also referred to as a tail-cone) 129 in which the pull rate was increased to terminate crystal growth. It should be noted that the various segments of the ingot 114 are shown for illustration and should not be limited to various proportional lengths and/or thicknesses.

In the illustrated embodiment, the first axial region 133 is shown closer to the seed end 145 of the constant diameter portion. In other embodiments, the first axial portion may be closer to the terminal end 149 and the second axial portion may be closer to the seed end 145 (i.e., the axial portion with the higher resistivity may be toward either end of the constant diameter portion). Additional axial portions having different resistivities may also be included in the ingot (e.g., third, fourth or more doped axial regions).

In some embodiments, the constant diameter portion 127 has a length as measured from the seed end 145 to the terminal end 149 of less than 4,500 mm, less than 3,000 mm, less than 2,000 mm or even less than about 1,500 mm or at least about 1,500 mm, at least about 2,000 mm, at least about 3,000 mm, or at least about 4,000 mm, and even up to about 4,500 mm (e.g., from about 1,500 mm to about 4,500 mm or from about 2,000 mm to about 4,000 mm).

Ingots grown according to the method 300 may be grown to any suitable diameter that enables the methods to be performed as described herein. In some embodiments, the method 300 includes growing a crystal ingot to a diameter of no less than about 150 mm, no less than about 200 mm, no less than about 300 mm, no less than about 400 mm, and even up to about 450 mm.

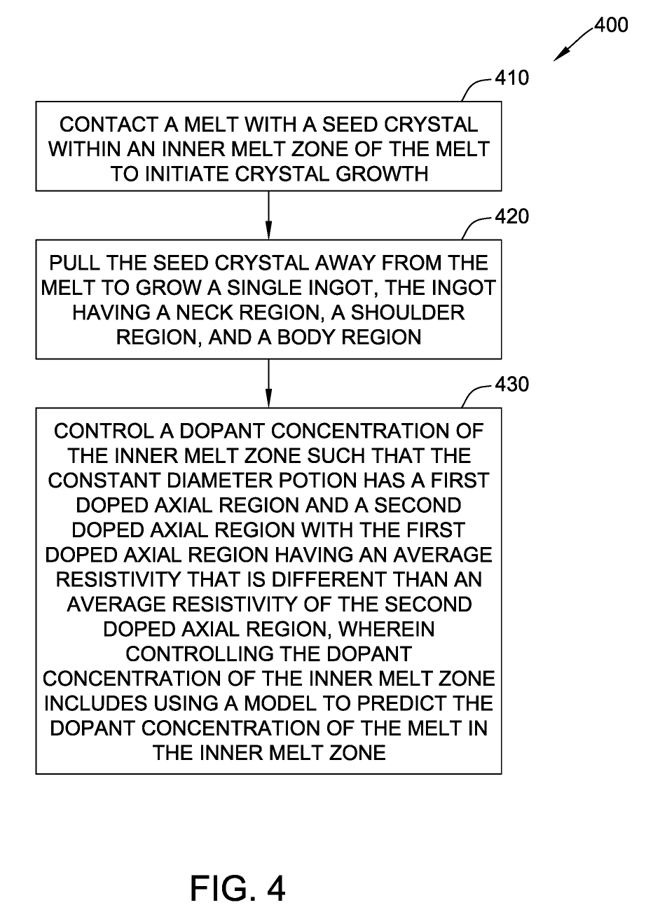

FIG. 4 is a flow chart of another embodiment of a method 400 of growing a single crystal silicon ingot having a first doped axial region and a second doped axial region from a melt. The melt includes an inner melt zone separated from an outer melt zone by one or more fluid barriers. The method 400 generally includes contacting 410 the melt with a seed crystal within the inner melt zone to initiate crystal growth, pulling 420 the seed crystal away from the melt to grow a single crystal ingot, the ingot having a neck region, a shoulder region, and a constant diameter portion, controlling 430 a dopant concentration of the inner melt zone such that the constant diameter portion has a first doped axial region and a second doped axial region with the first doped axial region having an average resistivity that is different than an average resistivity of the second doped axial region, wherein controlling the dopant concentration of the inner melt zone includes using a model to predict the dopant concentration of the melt in the inner melt zone.

The model used to predict dopant concentration of the melt in the inner melt zone may be based at least in part on diffusion of the dopant between the inner melt zone and the outer melt zone, evaporation of the dopant from the melt, segregation of the dopant from the ingot being grown, and convective mass transfer between the inner melt zone and the outer melt zone.

In some embodiments, the method 400 may further include determining at least one of a mass transfer coefficient for the dopant within the melt, an effective segregation coefficient of the dopant, and an evaporation coefficient of the dopant. In some embodiments, the coefficients are determined empirically based on one or more Czochralski growth processes. The coefficients may be used with the model to predict the dopant concentration of the melt in the inner melt zone, and to control the dopant concentration of the melt within the inner melt zone. In some embodiments, for example, one or both of the initial dopant amount and the dopant feed rate for the first doped axial region and a second dopant amount and/or second feed rate for the second doped axial region are calculated based on at least one of the determined mass transfer coefficient, the determined effective segregation coefficient, and the determined evaporation coefficient.

The methods and models described herein are also particularly well suited for doping melts with relatively large amounts of dopants such that one or more of the doped axial regions of the ingot have a relatively low resistivity. In particular, the methods and models described herein facilitate maintaining a melt at or near a constitutional supercooling limit associated with a dopant and a melt temperature to achieve relatively low resistivities in ingots grown from the melt. In some embodiments, for example, dopants are added to the melt to achieve a dopant concentration in the melt of no less than about 1×10¹⁸ atoms/cm³, no less than about 1×10¹⁹ atoms/cm³, and even up to about 1×10²⁰ atoms/cm³. By providing an accurate model to predict the dopant concentration of the inner melt zone from which an ingot is grown, the dopant concentration can be maintained at or near the constitutional supercooling limit without exceeding the limit, which could result in rapid dendritic growth and loss of the single crystalline structure of the ingot. Accordingly, in some embodiments, controlling 430 the dopant concentration of the inner melt zone during growth of the first and second axial regions further includes maintaining the dopant concentration of the inner melt zone near a constitutional supercooling limit associated with the dopant concentration, ingot growth rate, temperature and temperature gradient of the melt.

In some embodiments, controlling 430 the dopant concentration of the inner melt zone may include controlling the dopant concentration of the inner melt zone such that the resistivity of the first axial region has an average resistivity that is at least about 0.1 mΩ-cm less than an average resistivity of the second doped axial region. In some embodiments, the dopant concentration in the inner melt zone is controlled such that the first axial region has an average resistivity that is at least about 0.1 mΩ-cm less than an average resistivity of the second doped axial region, with the first and second doped axial regions having a length of at least about 750 mm and the resistivity within each of the first and second doped axial regions not varying by more than 15%.

In some embodiments, the dopant concentration in the inner melt zone is controlled such that the first axial region has an average resistivity that is at least about 0.15 mΩ-cm less than an average resistivity of the second doped axial region or at least about 0.20 mΩ-cm less or even at least about 0.30 mΩ-cm less than an average resistivity of the second doped axial region. Alternatively or in addition, each of the first and second axial regions may have a length of at least about 1,000 mm or even at least about 1,250 mm. The length of the first and second doped axial regions may be less than about 4,000 mm, less than about 3,500 mm, less than about 3,000 mm, less than about 2,500 mm, less than about 2,000 mm, less than about 1,500 mm or less than about 1,000 mm.

The first and second axial regions having different resistivities (and/or third or fourth regions, if any) may be separated by a transition zone in which the resistivity changes to approach the average resistivity. For example, the transition zone may have a length of 400 mm or less, 300 mm or less, 200 mm or less or even 100 mm or less (e.g., 25 mm to about 400 mm or from about 100 mm to about 400 mm). The length of the transition zone may depend, on part, the degree of change of resistivity between zones. The start of the transition zone may correspond to the point at which additional dopant was added to the melt.

In some embodiments, the ingot contains additional doped axial regions that have a resistivity different than that of the first and/or second doped regions (e.g., that has an average resistivity that is at least about 0.1 mΩ-cm more or less than an average resistivity of the first doped axial region and/or the second doped axial region or even about 0.15 mΩ-cm, at least about 0.20 mΩ-cm or even at least about 0.30 mΩ-cm more or less than an average resistivity of the first doped axial region and/or the second doped axial region). The additional regions may have a length within the ranges stated above and/or a resistivity variance within the stated ranges. For example, the ingot may include a third doped axial region having an average resistivity that is at least about 0.1 mΩ-cm more or less than an average resistivity of the first doped axial region and/or the second doped axial region, and having a length of at least about 750 mm. In some embodiments, the resistivity within the third axial region may vary by no more than 15%.

In some embodiments, the constant diameter portion of the ingot includes a fourth doped axial region. For example, the fourth region may have an average resistivity that is at least about 0.1 mΩ-cm more or less than an average resistivity of the first doped axial region, second doped axial region and/or third doped axial region and having a length of at least about 750 mm. In some embodiments, the resistivity within the fourth axial region may vary by no more than 15%.

The resistivity may vary within each doped axial region by an amount less than 15% such as by no more than 10% within the region, no more than 7%, no more than 5%, no more than 3%, no more than 2%, or no more than 1% within each respective region.

The average resistivity may be measured by sampling the axial doped region at a number of points along its length and measuring the resistivity of the samples at the same radial position. For example, the resistivity may be measured by cutting slugs at eight points along the constant diameter portion of the ingot such as at point less than 5%, at 5%, 10%, 30%, 50%, 70%, 90% and 100% of the length of the axial doped region. The variance in resistivity across a length of a doped axial region may also be measured by sampling the ingot at points along its length and measuring the resistivity of the samples at the same radial position (e.g., eight sampling points occurring at less than 5%, at 5%, 10%, 30%, 50%, 70%, 90% and 100% of the length of the axial doped region).

In some embodiments, the method includes growing multiple ingots from the melt, where each ingot has first and second doped axial regions each having a substantially uniform axial resistivity profile. In some embodiments, for example, the ingot is a first ingot, and the method further includes removing the first ingot from the melt, growing a second ingot from the melt having a constant diameter portion, determining a first target resistivity for the first doped axial region and a second target resistivity for the second doped axial region of the second ingot, controlling the addition of dopant to the melt such that the first doped axial region has the first target resistivity and the second doped axial region has the second target resistivity. The second ingot having first and second doped axial regions may be characterized by the parameters noted above relating to the first ingot (e.g., length of axial regions, resistivity differences and resistivity variance within regions, etc.). The ingot growth method may be repeated for multiple ingots, e.g. up to about 6, 10, 15, 20 or more ingots.

In some embodiments, a relatively large amount of initial dopant (e.g., as compared to the dopant feed rate used to maintain the dopant concentration of the melt during ingot growth) is added to the outer melt zone only after crystal growth is initiated, such as during formation of at least one of a neck region of the ingot, a shoulder region of the ingot, and a body region of the ingot. In some embodiments, adding the initial amount of dopant includes adding the initial amount of dopant to a transition melt zone (e.g., transition melt zone 212, shown in FIG. 2) between the inner melt zone and an outermost melt zone of the melt. Further, in some embodiments, adding the initial amount of dopant includes adding the initial amount of dopant in multiple doses, where each dose is added at a different time so as to avoid a spike in dopant concentration that may exceed the constitutional supercooling limit associated with the dopant. In other embodiments, adding the initial amount of dopant includes adding the initial amount of dopant before necking, or before initiation of crystal growth.

Compared to conventional methods, the methods for preparing ingots by the embodiments of the present disclosure have several advantages. The methods described herein facilitate the production of multiple, single crystal semiconductor or solar grade silicon ingots that are doped with one or more dopants. In some aspects, for example, the methods described herein facilitate controlling the axial resistivity profile of ingots grown by the cCZ method using a model to predict dopant concentration of the growth zone of a melt at any point during the cCZ process to prepare an ingot having two or more doped axial regions with different resistivities. In particular, the methods described herein control the addition of dopants to a melt so as to form the two doped axial regions using a model that predicts dopant concentration in the melt based on, among other things, dopant evaporation, convective mass transport between adjacent melt zones, diffusion between adjacent melt zones resulting from dopant concentration gradients, and dopant segregation from the ingot being grown. By accounting for numerous dopant transport mechanisms, the methods described herein enable the production of single crystal ingots having two doped axial regions with substantially uniform axial resistivity profiles within each region.

### EXAMPLES

The processes of the present disclosure are further illustrated by the following Examples. These Examples should not be viewed in a limiting sense.

### Example 1

### Single Crystal Ingot with Three Doped Regions

An arsenic-doped monocrystalline silicon ingot was grown in a three melt zone crystal growing system having a configuration similar to the crystal growing system 100 shown in FIG. 1. A silicon melt was prepared in a crucible, and an initial amount of arsenic was added to the outer melt zone of the melt during a stabilization period. A seed crystal was lowered into contact with the melt to initiate crystal growth.

After several hours of ingot growth, additional arsenic was added to the outer melt zone to lower the resistivity of the ingot to less than 1.9 mΩ-cm in a second doped region. After several more hours of ingot growth, additional arsenic was added to the outer melt zone to further lower the resistivity in a third doped axial region of the ingot in which the resistivity was less than 1.8 mΩ-cm.

After the constant diameter portion (200 mm) of the ingot was grown, the ingot was subsequently removed from the crystal growing system, and slugs were cut from the ingot. Slugs were selected for analysis from various lengths from the seed end of the ingot body. Each slug was tested for resistivity at the center of the slug.

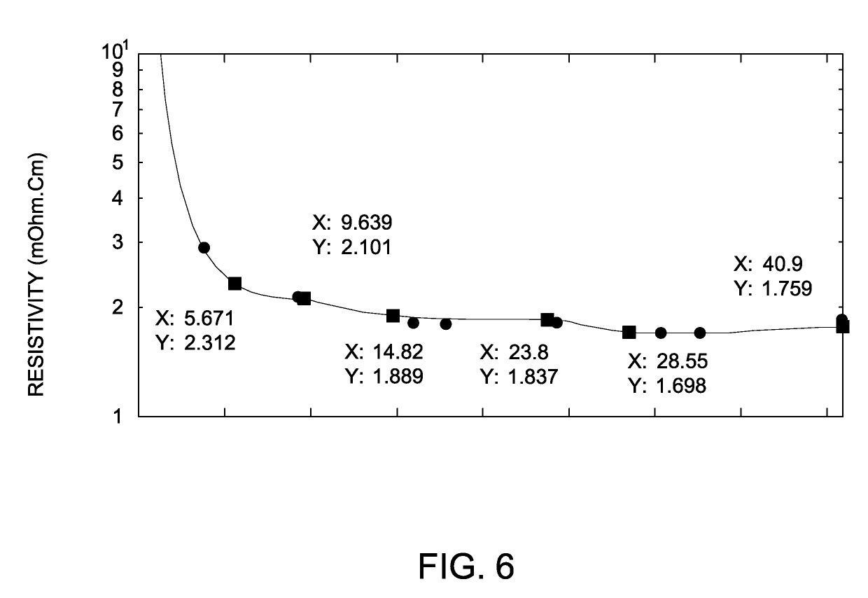

The measured resistivity values are shown in FIG. 6, and are plotted as a function of time during the Czochralski growth process, using the time at which the initial amount of dopant was added as the starting time. Specifically, the measured resistivity values from the ingot in Example 1 are indicated by the circles in FIG. 6.

The coefficients from Equations 2-4 were empirically determined using the measured resistivity values from the ingot. Specifically, the measured resistivity values were related to the dopant concentration of the ingot using resistivity conversion tables standard in the art, such as standard SEMI MF723-0307 and SEMI F723-99, published by SEMI International Standards. The dopant concentration of the melt was then determined for each point in time corresponding to the axial position of the ingot from which each slug was selected using Equation 5 above. The coefficients from Equations 2-4 were then determined by solving the set of differential equations. The theoretical resistivity values predicted by the above model using the determined coefficients are plotted in FIG. 6 with the coordinates of the squares being shown for illustration.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A method of growing a single crystal silicon ingot from a melt including an inner melt zone separated from an outer melt zone by one or more fluid barriers, the single crystal silicon ingot having a constant diameter portion with a first doped axial region and a second doped axial region, the method comprising:
determining a first target resistivity for the first doped axial region;
determining a second target resistivity for the second doped axial region, the second target resistivity being different than the first target resistivity;
contacting the melt with a seed crystal within the inner melt zone to initiate crystal growth;
pulling the seed crystal away from the melt to grow a single crystal ingot having the first doped axial region and the second doped axial region;
controlling the addition of dopant to the melt such that the first doped axial region has the first target resistivity; and
controlling the addition of dopant to the melt such that the second doped axial region has the second target resistivity.

2. The method as set forth in claim 1 wherein controlling the addition of dopant to the melt comprises calculating a first dopant amount to form the first doped axial region and calculating a second dopant amount to form the second doped axial region.

3. The method as set forth in claim 1 wherein controlling the addition of dopant to the melt comprises calculating a first dopant feed rate to form the first doped axial region and calculating a second dopant feed rate to form the second doped axial region.

4. The method as set forth in claim 1 comprising controlling the dopant concentration of the inner melt zone such that the first doped axial region has an average resistivity that is at least about 0.1 mΩ-cm less than an average resistivity of the second doped axial region.

5. The method as set forth in claim 1 wherein the resistivity within the first axial region varies by no more than 15% and the resistivity within the second axial region varies by no more than 15%.

6. The method as set forth in claim 5 wherein the variance is measured by sampling the ingot at eight points along its length and measuring the resistivity of the samples, the sampling points occurring at a point less than 5%, at 5%, 10%, 30%, 50%, 70%, 90% and 100% of the length of the axial doped region.

7. The method as set forth in claim 1 comprising controlling a dopant concentration of the inner melt zone such that the constant diameter portion has a third doped axial region, the third doped axial region having an average resistivity that is at least about 0.1 mΩ-cm more or less than an average resistivity of the first doped axial region and/or the second doped axial region, the third doped axial region having a length of at least about 750 mm, the resistivity within the third axial region varying by no more than 15%.

8. The method as set forth in claim 1 wherein the first and second target resistivities are upper limits of a resistivity range.

9. The method as set forth in claim 1 wherein controlling the addition of dopant to the melt such that the first doped axial region has the first target resistivity and the controlling the addition of dopant to the melt such that the second doped axial region has the second target resistivity includes using a model to predict the dopant concentration of the melt in the inner melt zone.

10. A method of growing a single crystal silicon ingot having a first doped axial region and a second doped axial region from a melt including an inner melt zone separated from an outer melt zone by one or more fluid barriers, the method comprising:
contacting the melt with a seed crystal within the inner melt zone to initiate crystal growth;
pulling the seed crystal away from the melt to grow a single crystal ingot, the ingot having a neck region, a shoulder region, and a constant diameter portion; and
controlling a dopant concentration of the inner melt zone such that the constant diameter portion has a first doped axial region and a second doped axial region with the first doped axial region having an average resistivity that is different than an average resistivity of the second doped axial region, wherein controlling the dopant concentration of the inner melt zone includes using a model to predict the dopant concentration of the melt in the inner melt zone.

11. The method as set forth in claim 10 wherein the model is based at least in part on diffusion of the dopant between the inner melt zone and the outer melt zone.

12. The method as set forth in claim 10 wherein controlling the dopant concentration of the inner melt zone includes:
calculating an initial amount of dopant to be added to the melt to form the first doped axial region;
adding the initial amount of dopant to the melt;
calculating a second amount of dopant to be added to the melt to form the second doped axial region; and
adding the second amount of dopant to the melt.

13. The method as set forth in claim 10 wherein controlling the dopant concentration of the inner melt zone includes:
calculating an initial amount of dopant to be added to the melt;
adding the initial amount of dopant to the melt;
calculating a first dopant feed rate for dopant to be supplied to the melt during growth of the first doped axial region;
adding dopant to the melt according to the first dopant feed rate;
calculating a second dopant feed rate for dopant to be supplied to the melt during growth of the second doped axial region; and
adding dopant to the melt according to the second dopant feed rate, wherein the first dopant feed rate and the second dopant feed rate are calculated using the model to predict the dopant concentration of the melt in the inner melt zone.

14. The method as set forth in claim 13 further comprising determining a mass transfer coefficient for dopant within the melt, wherein calculating the first and second dopant feed rates includes calculating the first and second dopant feed rates based on the determined mass transfer coefficient.

15. The method as set forth in claim 13 further comprising determining a mass transfer coefficient for dopant within the melt, wherein calculating the initial amount of dopant includes calculating the initial amount of dopant based on the determined mass transfer coefficient.

16. The method as set forth in claim 10 comprising controlling the dopant concentration of the inner melt zone such that the first doped axial region and the second doped axial region both have a length of at least about 1250 mm.

17. The method as set forth in claim 10 wherein the resistivity within the first axial region varies by no more than 15% and the resistivity within the second axial region varies by no more than 15%.

18. The method as set forth in claim 17 wherein the variance is measured by sampling the ingot at eight points along its length and measuring the resistivity of the samples, the sampling points occurring at a point less than 5%, at 5%, 10%, 30%, 50%, 70%, 90% and 100% of the length of the axial doped region.

19. The method as set forth in claim 10 comprising controlling a dopant concentration of the inner melt zone such that the constant diameter portion has a third doped axial region, the third doped axial region having an average resistivity that is at least about 0.1 mΩ-cm more or less than an average resistivity of the first doped axial region and/or the second doped axial region, the third doped axial region having a length of at least about 750 mm, the resistivity within the third axial region varying by no more than 15%.

20. The method as set forth in claim 10 wherein the average resistivity is measured by sampling the ingot at eight points along its length and measuring the resistivity of the samples, the sampling points occurring at a point less than 5%, at 5%, 10%, 30%, 50%, 70%, 90% and 100% of the length of the axial doped region.

21. A single crystal silicon ingot comprising a constant diameter region, the constant diameter portion having a first doped axial region and a second doped axial region, each of the first and second doped regions being doped with an electrically active dopant, wherein the first doped axial region has an average resistivity that is at least about 0.1 mΩ-cm less than an average resistivity of the second doped axial region, the first doped axial region and the second doped axial region both having a length of at least about 750 mm, the resistivity within the first axial region varying by no more than 15% and the resistivity within the second axial region varying by no more than 15%.

22. The single crystal silicon ingot as set forth in claim 21 wherein the electrically active dopant is a P-type dopant selected from the group consisting of boron, aluminum, gallium and indium or an N-type dopant selected from the group consisting of phosphorous, arsenic and antimony.

23. The single crystal silicon ingot as set forth in claim 21 wherein the electrically active dopant is selected from the group consisting of arsenic, antimony, red phosphorous, and indium.

24. The single crystal silicon ingot as set forth in claim 21 wherein the average resistivity is measured by sampling the ingot at eight points along its length and measuring the resistivity of the samples, the sampling points occurring at a point less than 5%, at 5%, 10%, 30%, 50%, 70%, 90% and 100% of the length of the axial doped region.

25. The single crystal silicon ingot as set forth in claim 21 wherein the variance is measured by sampling the ingot at eight points along its length and measuring the resistivity of the samples, the sampling points occurring at a point less than 5%, at 5%, 10%, 30%, 50%, 70%, 90% and 100% of the length of the axial doped region.

26. The single crystal silicon ingot as set forth in claim 21 wherein the resistivity of both the first and second regions varies by no more than 5% within the region.
